(19) United States
(12) Patent Application Publication
(10) Pub. No.: US 2008/0210291 A1
(43) Pub. Date: Sep. 4, 2008

(54) Solar collector and photovoltaic converter

(76) Inventor: Charles M. Grimm, Carmel, IN (US)

Correspondence Address: Frank D. Lachenmaier, 116 N. Main St., P.O. Box 1047, Kokomo, IN, 46903-1047, US

(21) Appl. No.: 11/713,225

(22) Filed: Mar. 2, 2007

(51) Int. Cl. H01L 31/04

(52) U.S. Cl. 136/246

(57) ABSTRACT

This invention relates generally to a solar collector and photovoltaic converter with a concentrating reflective inner surface with a static fluid filter attached to the bottom half of a enclosure with a photovoltaic converter cell mounted to the under side of the hemi-spherical transparent top half of the enclosure.

### BACKGROUND

1. Field of Invention

This invention relates generally a solar collector with a concentrating reflective surface with a static fluid IR filter attached to the bottom of a transparent enclosure with a photovoltaic converter device or cell mounted to the under side of the top of a transparent enclosure.

2. Prior Art

Photovoltaic device surfaces need to remain relatively cool to operate at maximum efficiency. There is a narrow spectrum of photon wavelengths that trigger a generation of electricity event when they impact the surface of photovoltaic device. All the photons in the tails of that spectrum outside the electricity generation segment only cause unwanted heating of the photovoltaic device, reducing its efficiency. Currently solar collectors use many different methods to avoid overheating of photovoltaic devices. Some use expensive Fresnel lenses to reflect the longer wavelengths that are not convertible by the cell away from the photovoltaic device and only serve to heat the photovoltaic device. Others pump a fluid such as water between the source and the reflector or between the cell and the reflector that will absorb the infrared spectrum, heating the fluid. They then reclaim the heat absorbed by the fluid by cycling this heated fluid through some type of heat exchanger using some of the electricity generated by the photovoltaic devices to pump the fluid. Water or a fluid with similar properties at a depth of ½ inch does an excellent job of filtering out the IR wavelength photons. Various dyes can be added to the fluid to also filter out the red, yellow and green wavelength photons which also are not convertible and only add heat. Depending on the concentration ratio which equals approximately the area of photovoltaic device face divided by the area of the inlet window, this may or may not be required. Secondary film filters can also be added to the underside of the inlet window to filter out the UV rays if required. Some do not utilize concentrators but rely on large surface area cells which must be kept clear of dust to be effective.

### SUMMARY

The general object of the present invention is to provide an economical solar collector and conversion apparatus.

The specific objective of this invention is to provide a very low cost system for the generation of sufficient power to provide for the basic needs of a family in remote undeveloped regions of the world or for first responders in emergency relief of victims of hurricanes, tornadoes, earthquakes or tsunamis where there are sure to be significant power outages that:
1. serves as a solar collector and power generating apparatus with little to no maintenance required and can generate potable water as a byproduct of its operation.
2. serves as a solar collector and power generating apparatus where the photovoltaic device is sheltered from dust and other contaminates.
3. serves as a solar collector and power generating apparatus where the portion of the incoming radiation that is of unconvertible wavelengths by a photovoltaic device is filtered prior to impact on the concentrating reflector.
4. serves as a solar collector and power generating apparatus where a significant portion of the effective wavelength photons of the impending radiation is reflected onto the face of a photovoltaic device.
5. serves as a solar collector and power generating apparatus that can function setting on ground or water.

### DRAWINGS

In order that the invention may be more fully understood it will now be described by way of example, with reference to the accompanying drawings in which:

FIG. 1 is a front perspective view of a solar collector and photovoltaic converter showing an earth mounted embodiment.

FIG. 2 is a section view of same.

FIG. 3 is a front perspective view of a solar collector and photovoltaic converter showing a floating on water embodiment.

FIG. 4 is a section view of same.

FIG. 5 is an enlarged view of FIG. 4 showing solar radiation entrance, reflection and escape patterns.

### REFERENCE NUMERALS

The same reference numbers are used to refer to the same or similar parts in the various views.

| | |
|---|---|
| 10 | solar collector and photovoltaic |
| | converter |
| 12 | bottom enclosure |
| 14 | bottom reflective inner surface |
| 16 | long wave length filter packet |
| 18 | filter fluid |
| 20 | photovoltaic device |
| 22 | output cable |
| 24 | top reflective inner surface |
| 26 | inflation valve |
| 28 | top enclosure |
| 30 A | solar ray directly reflected to |
| | photovoltaic device |
| 30 B | solar ray indirectly reflected |
| | to photovoltaic device |
| 30 C | solar ray escaping collector |
| 32 | mounting skirt |
| 34 | inlet window |
| 36 | UV filter |

### DESCRIPTION

In order that the invention may be more fully understood, solar collector and photovoltaic converter 10 will now be described by way of example with reference to the accompanying drawings.

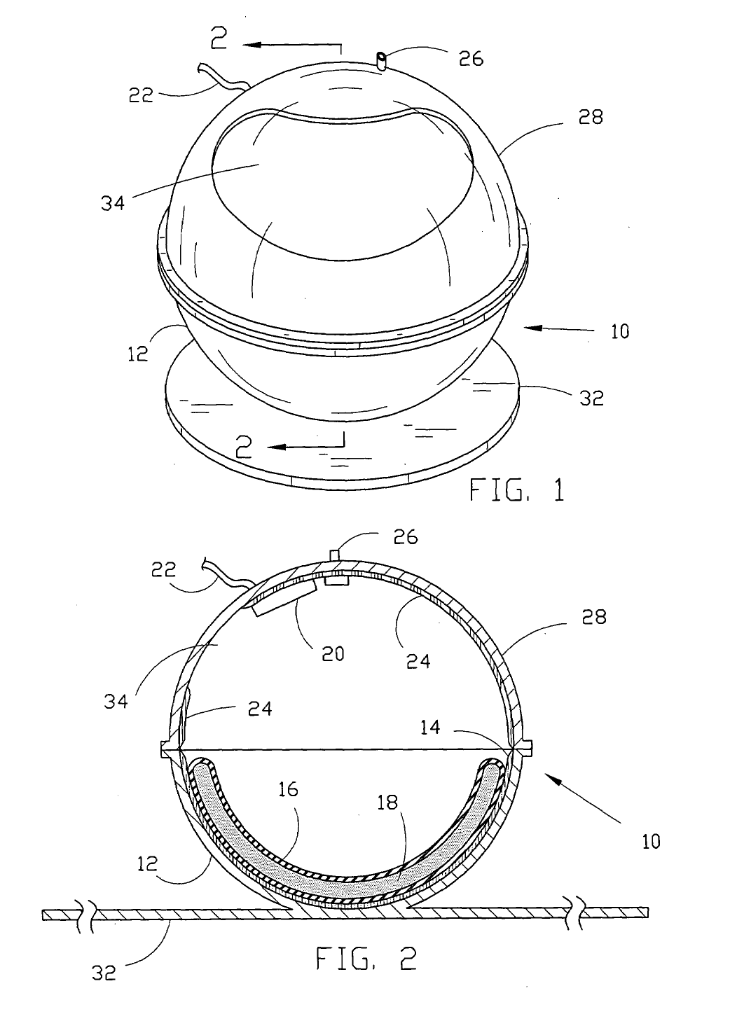

FIG. 1 illustrates an embodiment of solar collector and photovoltaic converter 10 for a land based fixed location mounting. It is comprised of bottom enclosure 12 that is open to the top with a bottom reflective inner surface 14. This bottom reflective inner surface 14 takes on the shape of bottom enclosure 12. Top Enclosure 28 is a transparent hemisphere with the same outside diameter as bottom enclosure 12. Top reflective inner surface 24 covers the inside of top enclosure 28 with the exception of inlet window 34. Photovoltaic device 20 is mounted toward the inside top of top enclosure 28.

FIG. 2 is a view of a section through solar collector and photovoltaic converter 10. It shows long wavelength filter packet 16 that conforms to the inner surface of bottom enclosure 12. Long wavelength filter packet 16 is a sealed packet of transparent flexible or rigid material filled with filter fluid 18. If filter fluid 18 is water, a depth of approximately ½ inch is sufficient to filter out most of the radiation above 1.2 microns. Since solar rays 30 pass through filter fluid 18 the second time as they are reflected back through filter packet 16, a ¼ inch deep filter packet 16 will suffice. Red, yellow, green and UV rays below 0.35 microns are also non-convertible by photovoltaic cells and can be filtered out by admixing appropriate dyes with filter fluid 18 if required for high concentration ratio solar collector and photovoltaic converters 10.

Another embodiment covers entrance window 34 with thin film UV filter 36 for even higher concentration ratio solar collector and photovoltaic converters 10 as shown in enlarged view in FIG. 5.

The height of entrance window 34 ranges from approximately 30 degrees to 47 degrees. It is positioned on the face of solar collector and converter 10 at predetermined optimal positions based on where it will be utilized, to compensate for variations in the angles of incidence of solar rays 30 for various latitudes. The width of the entrance window 34 ranges from approximately 120 degrees to 200 degrees to allow for the daily variations of the angles of incidence in a land based system.

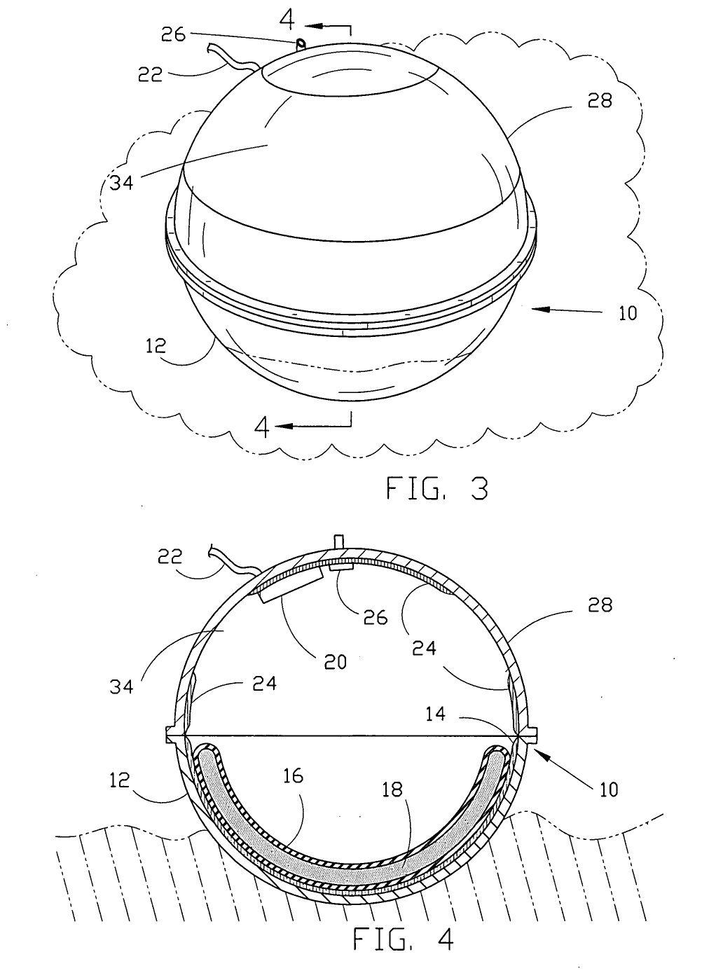

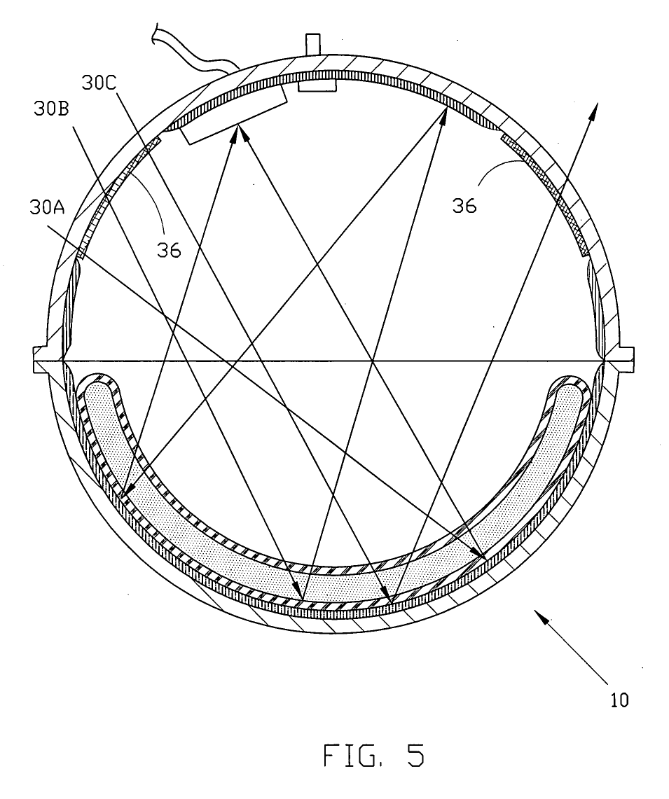

FIG. 3 illustrates an embodiment of solar collector and photovoltaic converter 10 for a water based mounting. It is comprised of bottom enclosure 12 that is open to the top with a bottom reflective inner surface 14. This reflective inner surface 14 takes on the shape of bottom enclosure 12. Top enclosure 28 is a transparent hemisphere with the same outside diameter as bottom enclosure 12. Top reflective inner surface 24 covers the inside of top enclosure 28 with the exception of inlet window 34 which runs completely around the circumference of top reflective inner surface 24. It is positioned on the face of solar collector and converter 10 at predetermined optimal positions based on where it will be utilized, to compensate for variations in the angles of incidence of solar rays 30 for various latitudes. Photovoltaic device 20 is mounted toward the inside top of top enclosure 28.

FIG. 4 is a view of a section through solar collector and photovoltaic converter 10. FIG. 4 shows long wavelength filter packet 16 that conforms to the inner surface of bottom enclosure 12. Long wave length filter packet 16 is a sealed packet of transparent flexible or rigid material filled with filter fluid 18. If filter fluid 18 is water, a depth of approximately ½ inch is sufficient to filter out most of the radiation above 1.2 microns. Since solar rays 30 pass through filter fluid 18 the second time as they are reflected back through filter packet 16, a ¼ inch deep filter packet 16 will suffice. Red, yellow, green and UV rays below 0.35 microns are also non-convertible by photovoltaic cells and can be filtered out by admixing appropriate dyes with filter fluid 18.

In one embodiment top enclosure 28 and bottom enclosure 12 are made from a rigid transparent material. In another they are made from a flexible material and the interior of the enclosure is inflated with a gas to give it shape. Inflation valve 26 is shown installed in top enclosure 28 for that purpose. In all embodiments output cable 22 is shown running from photovoltaic device 20 though top enclosure 28 and connecting to either an energy storage device or directly to a power consuming device such as a light, fan, cellular phone charger, etc, not shown in the drawings or part of this invention.

### Operation:

Standard photovoltaic devices 20 are able to convert photons of wave lengths between 0.35 and 1.2 microns to electricity. If the full spectrum of solar radiation were to impinge on the front surface of photovoltaic device 20, the photons above and below this range would only serve to heat the photovoltaic device 20, significantly reducing the efficiency with which it converts solar radiation 30 to electricity.

FIG. 1 shows an embodiment of solar collector and photovoltaic converter 10 with mounting skirt 32 attached to the bottom of bottom enclosure 12. This embodiment is designed for a ground installation. A clearing is constructed of sufficient diameter that solar radiation 30 is not blocked from inlet window 34 by surrounding buildings or vegetation. Solar collector and photovoltaic converter 10 is then placed on a bare patch of earth or sand with inlet window 34 facing in a southerly direction for a northern hemispheric location or a northern facing location for a southern hemispherical location. Rocks, dirt or other routine anchor mechanisms can be utilized to hold mounting skirt 32 in contact with the ground and keep solar collector and photovoltaic converter 10 in proper alignment. The earth, shaded by solar collector and photovoltaic converter 10, makes a very good heat sink for the heat energy absorbed by fluid 18 in filter packet 16.

FIG. 3 shows solar collector and photovoltaic converter 10 floating on a body of water. In this embodiment, inlet window 34 runs completely around top enclosure 28 since it is very difficult to maintain a South or North facing attitude with a floating on water installation. Incoming solar rays 30 penetrate transparent top enclosure 28 through inlet window 34 and pass through long wave filter packet 16 which is approximately ¼ inch thick and made from a either rigid or flexible transparent material. A filter fluid 18 such as water will absorb most of the long wavelength radiation or infrared radiation above 1.2 microns that would heat the photovoltaic device 20. Solar rays 30 pass through filter packet 16, reflect off of bottom reflective inner surface 14, and pass back through filter fluid 18. They continue to be reflected from the interior reflective surfaces 14 and 24 until they either escape from solar collector and photovoltaic converter 10 through inlet window 34 or impinge on photovoltaic device 20. If desired, red, yellow, green radiation and ultraviolet radiation below 0.35 microns can be filtered out by adding the appropriate dyes to filter fluid 18.

FIGS. 1 and 3 show section views of solar collector and photovoltaic converters 10 with inlet windows 34 that have been tailored to a latitude approximately midway in the US. One of the objectives of this invention is a completely static system with no moving parts in order to retain scalability of the system without having to consider large motors embodied in a solar tracking system and to maintain the possibility of low to no maintenance. A practical system depends on reflective surfaces 14 and 24, covering the inside of bottom and top enclosures 12 and 28 respectively with the exception of inlet window 34 whose height is determined by the seasonal variation in the incidence angle of solar radiation at a given latitude. The width of window 34 ranges from approximately 120 degrees to 200 degrees for a fixed position land based solar collector and photovoltaic converter 10 as in FIGS. 1 and 2 and is circumferential for water mounted installations as in FIGS. 3-5.

FIG. 5 shows incident solar rays 30A, 30B and 30C entering through entrance window 34 of cross sectional area X. Solar ray 30A penetrates transparent top enclosure 28 and UV filter 36 if present and the transparent material of top side wall of filter packet 16; passes through filter fluid 18 which absorbs about 50% of its long wave length radiation; penetrates the transparent material of bottom side wall of filter packet 16; is reflected from bottom reflective inner surface 14; passes back through filter packet 26, filter fluid 18 and filter packet 16 giving up almost the remainder of its long wave radiation and impinges on the active face of photovoltaic device 20.

Solar ray 30B will continue bouncing about the inside bottom enclosure 12 and top enclosure 28 until it either hits the face of photovoltaic device 20 causing an electricity generating event or as solar ray 30C illustrates, escapes back out inlet window 34. The percentage of incoming light escaping randomly is roughly the ratio of cross sectional area X of inlet window 34 to the total surface area of the bottom and top reflective inner surfaces Y. The concentrating factor of the device is the cross sectional area X−X/Y divided by the cross sectional area of the photovoltaic device Z. The bandwidth of acceptable light incident on photovoltaic device 20 without causing overheating is determined by the concentration factor of solar collector and photovoltaic converter 10. If the concentrating factor is 3/1, plain water will be quite acceptable as filter fluid 18. If the concentrating factor is 10/1 or higher, filtration of the red, green, yellow and perhaps the UV are required to avoid dramatically reducing the efficiency of photovoltaic device by overheating. FIG. 5 shows the installation of UV filter 36 attached to the underside of inlet window 34 for such a case.

One of the other most vital human needs for individuals in remote areas or in emergency relief circumstances is often potable water. A serendipitous effect of solar collector and photovoltaic converter 10 is the sterilizing effect that it has on filter water when sunlight is allowed to pass though it for several hours. For this purpose long wavelength filter packet can be drained of potable water and refilled several times per day providing again a subsistence level of potable water.

The preceding descriptions are for illustrative purposes and are not intended to limit the scope of this invention. The scope of the invention should be determined by the appended claims rather than by the specific examples given.

What is claimed is:

1. A solar collector and photovoltaic converter comprising:
a bottom of an enclosure with a bottom reflective inner surface;
a transparent packet of filtering fluid which is retained against said bottom reflective inner surface;
a transparent top of said enclosure with a top reflective inner surface with a inlet window in said upper reflective inner surface;
a photovoltaic device with a front face, mounted on the under side of said transparent top;
a power transmission cable connected between said photovoltaic device and an energy storage or consuming device whereby:
solar radiation entering said inlet window penetrates said packet of filtering fluid, impinges on said lower reflecting surface, is reflected back through said packet of filtering fluid and continues to bounce within said enclosure until it either strikes said front face of said photovoltaic device converting the filtered spectrum to electricity or escapes out said inlet window.

2. A solar collector and photovoltaic converter as in claim 1 wherein said filter fluid is water; and
after said solar radiation has passed through and been reflected back through said water for several hours said water becomes potable.

3. A solar collector and photovoltaic converter as in claim 1 wherein said filter fluid is chosen from a group that contains oils and water with red, yellow and green wavelength filtering chemicals.

4. A solar collector and photovoltaic converter as in claim 1 further comprising a skirt attached to said enclosure bottom that can be buried to provide for secure installation on bare earth.

5. A solar collector and photovoltaic converter as in claim 1 further comprising a seal between said top and bottom of enclosure whereby said converter can float on a body of water.

6. A solar collector and photovoltaic converter as in claim 1 wherein said top of said enclosure is chosen from a group containing a rigid transparent material and a flexible inflatable transparent material.

7. A solar collector and photovoltaic converter as in claim 1 wherein said bottom of said enclosure is chosen from a group containing a rigid material and a flexible inflatable material.

8. A solar collector and photovoltaic converter as in claim 1 further comprising a thin UV filter film covering said light inlet window whereby UV radiation is prevented from entering said window.

9. A solar collector and photovoltaic converter as in claim 1 wherein said inlet window in said top reflective inner surface is chosen from group comprised of windows whose width ranges from approximately 120 degrees to 360 degrees and whose height ranges from approximately 30 degrees to approximately 47 degrees.
